(19) United States
(12) Patent Application Publication
(10) Pub. No.: US 2016/0190427 A1
(43) Pub. Date: Jun. 30, 2016

(54) NANOFIBER WEB PIEZOELECTRIC MATERIAL OBTAINED BY ELECTROSPINNING POLYLACTIC ACID, METHOD OF PRODUCING SAME, PIEZOELECTRIC SENSOR COMPRISING SAME, AND METHOD OF MANUFACTURING THE PIEZOELECTRIC SENSOR

(71) Applicant: University-Industry Cooperation Group of Kyung Hee University, Gyeonggi-do (KR)

(72) Inventors: Kap Jin KIM, Gyeonggi-do (KR); Sol Jee LEE, Gyeonggi-do (KR); Anand Prabu Arun, Gyeonggi-do (KR); Sathiyanathan Ponnan, Gyeonggi-do (KR)

(73) Assignee: University-Industry Cooperation Group of Kyung Hee University, Gyeonggi-do (KR)

(21) Appl. No.: 14/979,512

(22) Filed: Dec. 27, 2015

(30) Foreign Application Priority Data
Dec. 30, 2014 (KR) 10-2014-0194161

(51) Int. Cl. H01L 41/08; B29C 47/00; D04H 1/728; H01L 41/113

(52) U.S. Cl. CPC H01L 41/082; H01L 41/1132; B29C 47/0076; B29C 47/0085; B29C 47/0021; B29C 47/0004; D04H 1/728; B29K 2067/046

(57) ABSTRACT

Disclosed are a nanofiber web piezoelectric material and a method of producing the same, wherein a spinning solution of polylactic acid (PLA) in a solvent is electrospun, yielding a nanofiber web, thereby exhibiting piezoelectric properties without additional drawing. This piezoelectric material is remarkably cost-effective, can exhibit superior piezoelectric properties, can be used to manufacture inexpensive piezoelectric products, and obviates any additional drawing because the PLA chain is drawn during electrospinning. The drawing force induced by a high electric field between the needle and the collector enables the formation of 3₁ helical β-crystal chains in a uniaxial direction even without any other drawing process. This PLA nanofiber web is very thin and flexible, the PLA chains are effectively aligned in an electric field direction due to the high DC voltage used for electrospinning, and helical β conformation is easily formed in a single process using electrospinning.

### BACKGROUND OF THE INVENTION

1. Field of the Invention

The present invention relates to a nanofiber web piezoelectric material obtained by electrospinning polylactic acid and a method of producing the same and, more particularly, to a piezoelectric material and a method of producing the same, in which a spinning solution of polylactic acid in a solvent is electrospun, yielding a nanofiber web, thereby exhibiting piezoelectric properties without an additional drawing process.

2. Description of the Related Art

Polylactic acid (PLA) is an environmentally friendly polymer known to have superior biodegradability and biocompatibility. Recently, many researchers have become interested in the piezoelectric properties of PLA, which is a substitute for conventional polymer piezoelectric materials such as polyvinylidene fluoride (PVDF) and polymers thereof (e.g. PVDF-TrFE). The piezoelectric properties of PLA are manifested by an asymmetric molecular structure in which atoms exhibit electric properties uniquely and independently in all directions around the carbon atom.

Typically, PLA shows a helical chain structure, which is known to have an α-crystal phase, which is the most thermally stable at room temperature. FIG. 1A illustrates the α-crystal phase having 10₃ helical conformation, and this crystal phase may be easily obtained when a film is formed using a melting process or a solution process. However, the PLA film thus obtained does not exhibit piezoelectric properties because the C═O dipole groups are randomly oriented in all directions) (360° along the main chain and thus the net dipole moment is zero.

When the α-crystalline PLA film is drawn in a uniaxial direction at a high draw ratio and/or high temperature, it may be converted into a μ phase having loose 3₁ helical conformation along the polymer chain (FIG. 1B). Furthermore, the PLA film, in which the C═O dipole groups are oriented in all directions (360°) along the main chain, may surprisingly manifest piezoelectric properties when undergoing external pressure.

The piezoelectric properties of PLA films have already been studied, and have been compared with those of PVDF films. PVDF films require a poling process that arranges the C—F dipoles in poling directions in order to show piezoelectric properties, but uniaxially drawn PLA films may manifest piezoelectric properties even without such a poling process. As for PLA, the C═O dipoles may not easily rotate due to strong interactions of helical structures, but β-helical structures resulting from the drawing process exhibit weaker interactions than the α-helical structures. As illustrated in FIG. 3, converting the helical structures of PLA is possible via the shear deformation effect (FIG. 2). As seen in FIG. 3, the helical conformation is distorted due to shear stress, whereby the sum of C═O dipoles is not zero, and thus the PLA sample may generate a piezoelectric signal in response to external pressure. The maximum piezoelectric properties are referred to as “shear piezoelectric properties”, as defined by d₁₄, which means that the piezoelectric signal is generated in a No. 1 direction (i.e. a thickness direction) when a film, obtained through uniaxial thermal drawing in a No. 3 direction, is deformed by external force applied in a No. 4 direction (i.e. a diagonal direction) (FIG. 4).

In this regard, there has been developed a physiological sensing belt (PSB) (FIGS. 5A and 5B) manufactured by inserting a piezoelectric PVDF film between two elastic textile bands to measure pulse waves, breathing and the movement of muscles. As such, the conductive electrodes disposed on the top and bottom of the PVDF film are coated with silicone rubber having electromagnetic shielding properties, thus improving the frictional force between the PVDF film sensor and the elastic fabric, thereby increasing the strength of the piezoelectric signal and also drastically reducing signal noise (FIG. 5A). In this way, the silicone rubber-coated PVDF film, which is inserted between the elastic bands, is classified as a PSB sensor, and the PVDF film positioned in the PSB may be used to monitor the heart rate, respiratory conditions, and muscle movement through deformation thereof when tied around the chest and ankle. When the elastic bands including the PVDF film undergo periodic pressure and stretching force (FIG. 5B), similar to periodic respiratory motion, the piezoelectric signal is generated. Many reports on the use of uniaxially drawn PVDF film sensors for generating piezoelectric signals have been made to date, but the PVDF films are expensive, making it difficult to broaden the scope of real-world application of piezoelectric film sensors. Hence, the present inventors have studied the piezoelectric properties of PLA nanofiber webs as well as drawn PLA films, in order to replace expensive PVDF film PSB sensors.

Electrospinning, which is a process that allows a polymer solution to flow between a capillary tube-shaped needle and a collector using high direct-current (DC) voltage, is very effective at manufacturing thin and flexible nano-diameter fibers, and electrospun nanofiber webs are being utilized in various fields of drug delivery, tissue engineering, bones, etc. The electrospun PVDF nanoweb is configured (FIG. 6) such that C—F dipoles are mainly oriented in an electric field direction during the electrospinning process without additional poling (e.g. direct poling or corona poling). Although a high interest is taken in the piezoelectric properties of drawn pure PLA films for piezoelectric sensors, such films are difficult to apply to a variety of fields because they still suffer from problems of thickness, brittleness, and the need for additional drawing.

### CITATION LIST

### Patent Literature

(Patent Document 1) Korean Patent No. 10-1322838

(Patent Document 2) Korean Patent No. 10-1331858

(Patent Document 3) Korean Patent No. 10-1384755

(Patent Document 4) Korean Patent No. 10-1384761

### SUMMARY OF THE INVENTION

Accordingly, an object of the present invention is to provide a piezoelectric material, which may replace piezoelectric PVDF films, which have broad applicability but are expensive.

Another object of the present invention is to provide a piezoelectric sensor having cost effectiveness and high efficiency using the piezoelectric material.

Still another object of the present invention is to provide a method of simply producing the piezoelectric material and a method of simply manufacturing the piezoelectric sensor.

An aspect of the present invention provides a nanofiber web piezoelectric material obtained by electrospinning a spinning solution of polylactic acid (PLA) in a solvent.

Another aspect of the present invention provides a method of producing a piezoelectric nanofiber web, comprising dissolving PLA in a solvent, thus preparing a spinning solution, and electrospinning the spinning solution, yielding a nanofiber web.

In the present invention, 80% or more of the monomer for PLA may comprise an L-isomer or a D-isomer. Lactic acid, which is a PLA monomer, is an optical isomer having two types of L-isomer and D-isomer (Chemical Formula 1), PLA comprising L-isomers is referred to as PLLA, and PLA comprising D-isomers is referred to as PDLA (Chemical Formula 2). In the present invention, the purity of each isomer in PLA has a great influence on the piezoelectric properties of the piezoelectric material. When 80% or more of the monomer for PLA comprises any one kind of isomer, regardless of the kind of isomer, desired piezoelectric properties may be exhibited. The total amount of the monomer for PLA is preferably 90% or more, more preferably 95% or more, and much more preferably 98% or more. Based on the results of analysis of piezoelectric properties of conventional materials obtained by electrospinning PLA and piezoelectric inorganic particles, pure PLA material, serving as a control, does not exhibit piezoelectric properties. This is due to the lack of consideration of the kind of isomer.

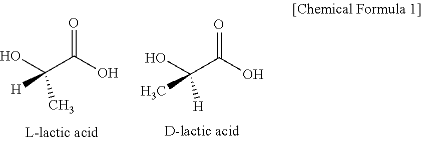

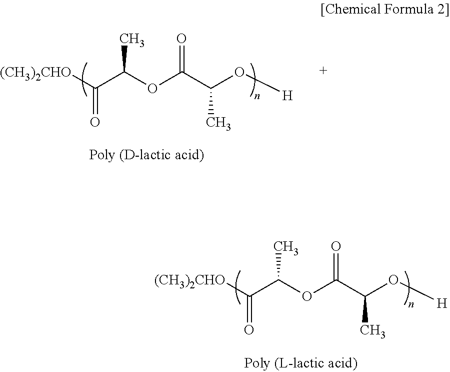

In the present invention, the solvent is preferably a mixture comprising chloroform and one of N,N-dimethylacetamide (DMAc), N,N-dimethylformamide (DMF) and dimethylsulfoxide (DMSO), and the volume ratio of chloroform and one of N,N-dimethylacetamide (DMAc), N,N-dimethylformamide (DMF) and dimethylsulfoxide (DMSO) is preferably set to 2:1 to 4:1. The spinning solution may be composed of 5 to 20 wt % of PLA dissolved in the above solvent. Under such conditions, a piezoelectric material (a piezoelectric nanofiber web) having superior effects may be more easily prepared.

Still another aspect of the present invention provides a piezoelectric sensor comprising the piezoelectric material and electrodes.

The piezoelectric sensor according to the present invention is configured such that the piezoelectric material is folded two times or more and stacked so that the same surface portions of the piezoelectric material face each other, and the electrodes are disposed between the folded surface portions of the stacked piezoelectric material and on the uppermost and the lowermost surface thereof. As such, the electrodes, in contact with the same surface portions based on the surface of the unfolded piezoelectric material, may be electrically connected to each other (FIG. 11D), which is regarded as having the same effect as connecting batteries in parallel. Thereby, the amount of current generated per unit of apparent cross-sectional area may be increased, and thus, when the piezoelectric material is used for the piezoelectric sensor, the piezoelectric sensitivity may increase, and also, when the piezoelectric material is used for a power generator (a power supply), charging current may increase.

The piezoelectric sensor according to the present invention may include a sensing unit, comprising the piezoelectric material and electrodes formed on both surfaces of the piezoelectric material, and an elastic layer for wrapping the sensing unit. It may be exemplarily configured as illustrated in FIG. 10. When the sensing unit is wrapped with the elastic layer in this way, external movement may be more efficiently transferred to the piezoelectric material, and the piezoelectric material may be protected, thus increasing durability. The elastic layer is preferably formed of silicone rubber in order to exhibit the above effects.

Yet another aspect of the present invention provides a method of manufacturing a piezoelectric sensor, comprising forming electrodes on both surfaces of the piezoelectric material.

In the method of manufacturing the piezoelectric sensor according to the present invention, the piezoelectric material is folded two times or more and stacked so that the same surface portions thereof face each other, and electrodes are provided between the folded surface portions of the stacked piezoelectric material and on the uppermost and the lowermost surface thereof. In particular, the electrodes, in contact with the same surface portions based on the surface of the unfolded piezoelectric material, may be electrically connected to each other.

Also, the method of manufacturing the piezoelectric sensor according to the present invention may further comprise forming an elastic layer for wrapping the sensing unit comprising the piezoelectric material and the electrodes.

The present invention is mainly intended to manufacture a sensor that may replace a PVDF film, which is generally useful but is expensive. Based on the results of research of the present invention, the PLA film having a draw ratio (DR) of 5 may exhibit high piezoelectric properties, compared to films exhibiting a DR of less than or greater than 5. The maximum piezoelectric signal is shown on the PLA film having a DR of 5 cut at 45°, corresponding to the main angular alignment of C═O dipoles. Sensors have been studied using three types of materials, including a typical PVDF film, a PLA film (DR=5 and cutting angle of 45°), and a pure PLA nanofiber web, based on the initial results, and these piezoelectric sensors are used to compare the generation of PSB signals in response to the respiratory pattern. Interestingly, the piezoelectric properties of the pure PLA nanofiber web are superior to those of the drawn PLA film. Based on the results of attenuated total reflectance infrared (ATR-IR) spectroscopy and on amplification of the piezoelectric signal of the constructive stacking nanofiber web sensor, the PLA nanofiber web may exhibit both drawing and poling effects in the electrospinning process, thus showing drawing effects and preferential C═O dipole orientation.

The sensors having various structures (stacking and folding) are manufactured in order to improve the piezoelectric properties of the pure PLA nanofiber web. As the number of layers of the nanofiber web is higher, the piezoelectric signal is amplified, but not linearly proportionate to the number of layers. Furthermore, the sensor configured such that the PLA nanofiber web is folded and electrodes are connected in parallel shows a signal at least nine times as high as the signals of other folded sensors. Finally, the sensor is applied as a high-performance power supply for charging a capacitor or operating an LED.

Compared to other known reports, the piezoelectric sensor having the electrodes connected in parallel according to the present invention may exhibit cost effectiveness and may be manufactured simply even without the use of any inorganic piezoelectric nanoparticles. Such a sensor may be used as an alternative to expensive PVDF piezoelectric sensors. The electrospun pure PLA nanofiber web may exhibit superior C═O dipole orientation, as in the typical PVDF sensor, and may also manifest excellent piezoelectric properties.

According to the present invention, a piezoelectric material is remarkably cost-effective, and can exhibit piezoelectric properties superior or similar to those of conventional PVDF piezoelectric materials. When the piezoelectric material of the present invention is used, piezoelectric products can be manufactured inexpensively. Also, the piezoelectric material according to the present invention obviates the need for any additional drawing process, because the PLA chain is drawn during the electrospinning. The drawing force induced by the strong electric field between the needle and the collector enables the formation of 3₁ helical β-crystal chains in a uniaxial direction even without any other drawing process (FIG. 7). Thereby, the piezoelectric material of the invention can be simply produced, compared to conventional PLA piezoelectric materials, which essentially require a drawing process after formation of the film.

Compared to PLA films, the PLA nanofiber web according to the present invention obtained using electrospinning is advantageous because the electrospun PLA nanofiber web is very thin and flexible, the PLA chains are effectively aligned in an electric field direction due to the application of high DC voltage upon electrospinning, and the formation of helical μ conformation in a single process using electrospinning is much easier.

### BRIEF DESCRIPTION OF THE DRAWINGS

The above and other objects, features and advantages of the present invention will be more clearly understood from the following detailed description taken in conjunction with the accompanying drawings, in which:

FIGS. 1A and 1B illustrate α- and β-crystal PLA chain structures;

FIG. 2 illustrates shear stress;

FIG. 3 illustrates the distortion of the PLA chain structure due to shear stress;

FIG. 4 illustrates the polarization of a uniaxially drawn PLA film, caused by shear stress;

FIG. 5A illustrates the silicone rubber-coated PVDF film sensor and the physiological sensing belt (PSB), and FIG. 5B illustrates the transverse cross-section of the body provided with PSB having the PVDF film;

FIG. 6 illustrates the C—F dipole properties of the PVDF nanofibers during the electrospinning;

FIG. 7 illustrates the electrospinning effect of the PLA nanofiber web produced on the collector;

FIG. 8 illustrates the dimension of the PLA film (right), used in the process of drawing the PLA film according to an embodiment of the present invention;

FIG. 9 illustrates the cutting angle upon manufacturing the PSB sensor using the drawn PLA film having a DR of 5 according to an embodiment of the present invention;

FIG. 10 illustrates the dimension and structure of the silicone rubber-coated PSB sensor according to an embodiment of the present invention;

FIGS. 11A, 11B, 11C and 11D illustrate the constructive/destructive stacking, multilayer stacking, three types of folding, and LED operation structure, respectively, as different structures of the piezoelectric sensors used in the example of the present invention;

FIG. 12 illustrates the simple equivalent circuit diagram for measuring the piezoelectric signal;

FIG. 13 illustrates the equivalent circuit diagram for charging a capacitor using the PLA nanofiber web sensor as a power source;

FIG. 14 illustrates the equivalent circuit diagram for operating an LED using the PLA nanofiber web sensor as a power source;

FIG. 15 illustrates the sample position (MD and TD) on the surface of a diamond used for ATR-IR spectroscopy;

FIGS. 16A and 16B illustrate the ATR-IR spectra of silicone rubber and electrospun PLA nanofiber web, respectively;

FIGS. 17A and 17B illustrate the ATR-IR spectra of undrawn PLA film, uniaxially drawn (×5) PLA film and pure PLA nanofiber web at positions of MD and TD, respectively;

FIGS. 18A, 18B, 18C, 18D, 18E, 18F and 18G illustrate the dynamic pressure test signals of PLA films drawn at various draw ratios of 1, 2, 3, 4, 4.5, 5 and 5.5, respectively, and FIG. 18H is a graph illustrating Vₚ₋ₚ relative to DR (Rᵢₙ=1 GΩ, Gain=0 dB);

FIGS. 19A, 19B, 19C, 19D and 19E illustrate the signals obtained by measuring (Rᵢₙ=1 GΩ, Gain=20 dB) the breathing of a person using PSB sensors manufactured using drawn PLA films (DR=5) at various cutting angles of 0°, 30°, 45°, 60° and 90°, respectively;

FIGS. 20A, 20B and 20C illustrate the field emission-scanning electron microscope (FE-SEM) images of the electrospun pure PLA nanoweb at magnifications of 2000×, 5000× and 100000×, respectively;

FIGS. 21A and 21B illustrate the signals of dynamic pressure testing (Rᵢₙ=1 GΩ, Gain=0 dB) of the piezoelectric sensors manufactured using electrospun pure PVDF nanofiber web and pure PLA nanofiber web, respectively;

FIGS. 22A and 22B illustrate the expected constructive and destructive stacking effects of the electrospun PVDF nanofiber web and PLA nanofiber web, respectively;

FIGS. 23A and 23B illustrate the piezoelectric signals (Rᵢₙ=1 GΩ, Gain=0 dB) of two-layer constructive and destructive stacking PVDF nanoweb sensors, respectively, and FIGS. 23C and 23D illustrate the piezoelectric signals (Rᵢₙ=1 GΩ, Gain=0 dB) of two-layer constructive and destructive stacking PLA nanofiber web sensors, respectively;

FIGS. 24A, 24B, 24C and 24D illustrate the piezoelectric signals of constructive stacking PLA nanofiber web sensors having one layer, three layers, five layers and eight layers, respectively, and FIG. 24E is a graph illustrating Vₚ₋ₚ depending on the number of layers (Rᵢₙ=1 GΩ, Gain=0 dB);

FIGS. 25A, 25B and 25C illustrate the piezoelectric signals of five-layer electrospun PLA nanowebs upon simple folding, folding with electrodes connected in series (Rᵢₙ=1 GΩ, Gain=0 dB), and folding with electrodes connected in parallel (Rᵢₙ=100 GΩ, Gain=0 dB) as shown in FIG. 11C, respectively; and

FIG. 26 is a graph illustrating the generation of current depending on the structures of three types of folded sensors.

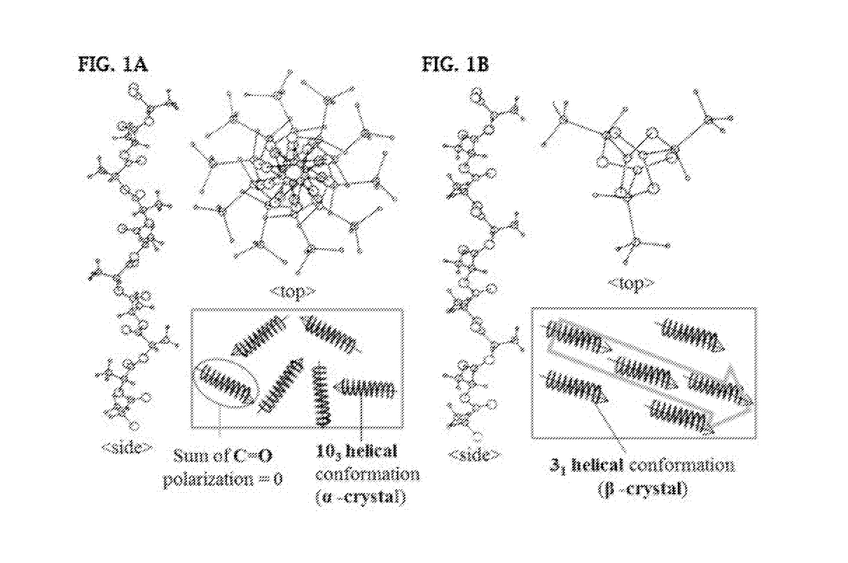

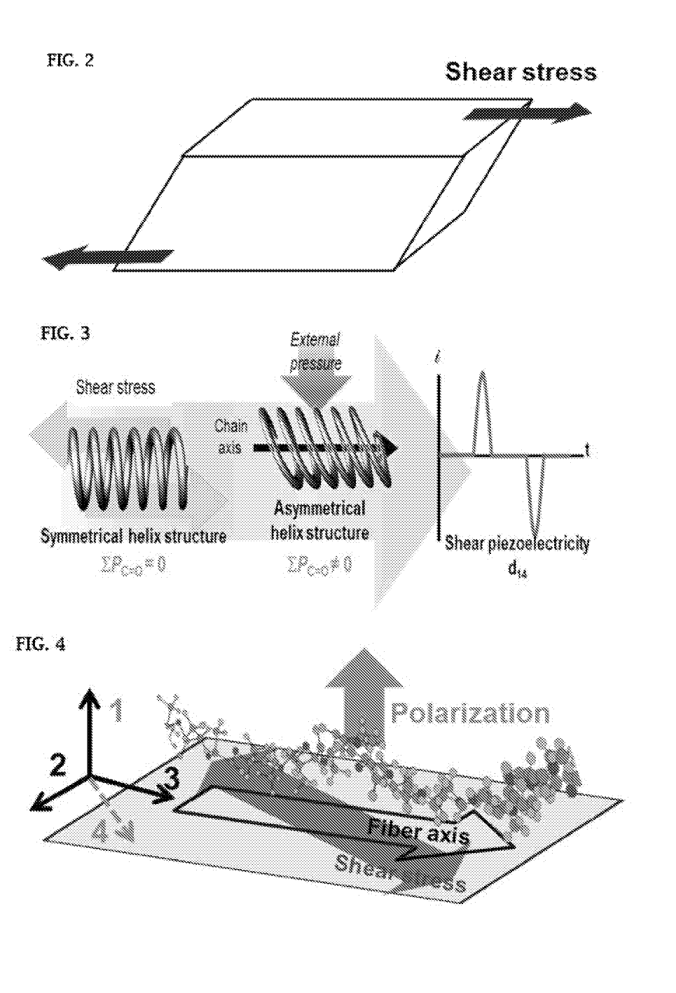

### DESCRIPTION OF THE PREFERRED EMBODIMENTS

Hereinafter, a detailed description will be given of the present invention through the following examples. These examples are merely set forth to illustrate the present invention, but are not to be construed to limit the scope of the present invention.

### Example 1

### Formation of Piezoelectric Material and Piezoelectric Sensor

### 1-1. Materials

In the present example, PLA 4032D (MW: 195,000), available from NatureWorks, USA, was used. In order to measure the respiratory signal in comparison with the case where a typical piezoelectric sensor is used, a poled PVDF film sensor (DT2-052) having top and bottom electrodes (thickness: 52 μm, width: 4 mm, length: 30 mm) was purchased from Measurement Specialties Inc. A silicone elastomer base and a silicone elastomer curing agent (Sylgard 184A and 184B, Dow Corning, Korea) were used for a silicone coating process for enhancing the frictional force of the elastic textile band while protecting the film or nanofiber web. Chloroform (CF), N,N-dimethylacetamide (DMAc), N,N-dimethylformamide (DMF) and dimethylsulfoxide (DMSO), available from Sigma-Aldrich Korea, were used as solvents for preparing the electrospinning solution. A Ni—Cu-plated polyester fabric having adhesiveness on one surface thereof (J.G. Korea Inc., Korea) was used as the electrode for a piezoelectric sensor.

### 1-2. PLA Processing

### 1-2-1. Uniaxially Drawn PLA Film

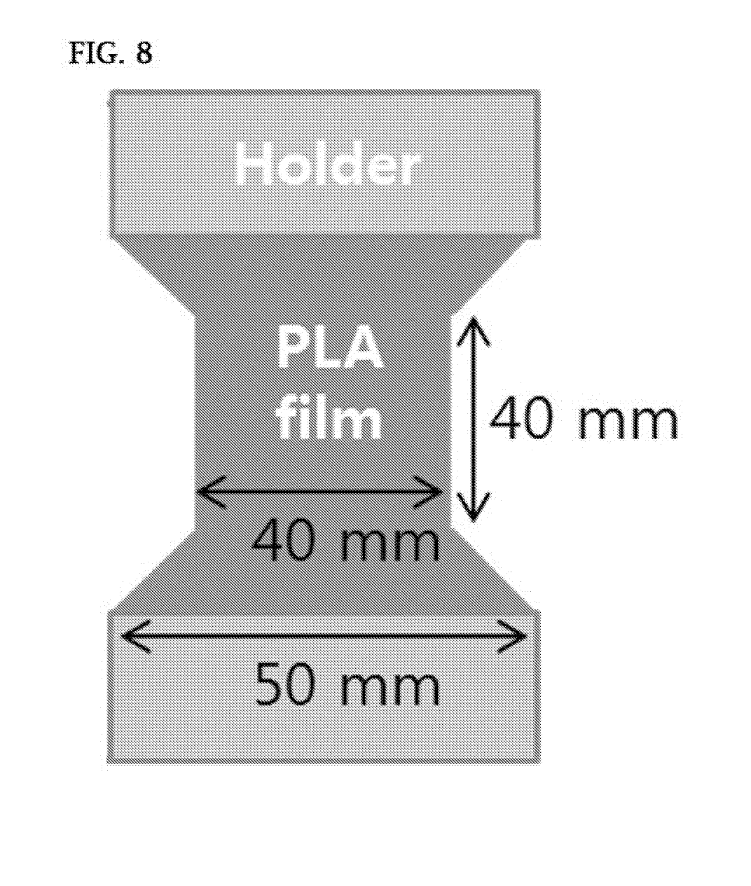

The PLA chips were dried at 100° C. for 6 hr in a vacuum, and then formed into PLA films using an extruder installed in the Korea Institute of Industrial Technology (KITECH). Table below shows the temperature of each extruder zone. To increase the width of the film before wrapping, aeration was performed at 130° C. The extruded PLA film was drawn at different draw ratios in a hot chamber using an Instron® tensile testing machine from FITI (Korea). Specifically, the PLA film was fixed to a holder (FIG. 8), maintained at 80° C. for 15 min in a hot chamber to reach thermal equilibrium, and then drawn at various draw ratios (DR: 2, 3, 4, 4.5, 5 and 5.5) at a speed of 750 mm/min.

TABLE 1
Temperatures set at individual zones of extruder

| Barrel 1 | Barrel 2 | Barrel 3 | Barrel 4 | Adapter | Spin block | Pack body | Air knife |
|---|---|---|---|---|---|---|---|
| 220° C. | 240° C. | 240° C. | 240° C. | 240° C. | 240° C. | 240° C. | 130° C. |

### 1-2-2. Electrospun Nanofiber Web

PLA was dissolved at 9 wt % (w/v) in a solvent mixture comprising chloroform (CF) and DMAc (or DMF or DMSO) (3:1 v/v), thus preparing a pure PLA solution for electrospinning. Specifically, PLA was completely dissolved in CF, and DMAc was then added to solve some electrospinning problems due to the use only of a solution of PLA and CF. 6 mL of the PLA solution was placed in a syringe, and then electrospun under the following conditions: a needle type of 18G, a flow rate of 1.5 cc/h, a voltage of 12 kV, a tip-to-collector distance (TCD) of 10 cm, and a collector rotating rate of 80 rpm.

### 1-3. Fabrication of Piezoelectric Sensor

### 1-3-1. PSB Sensor

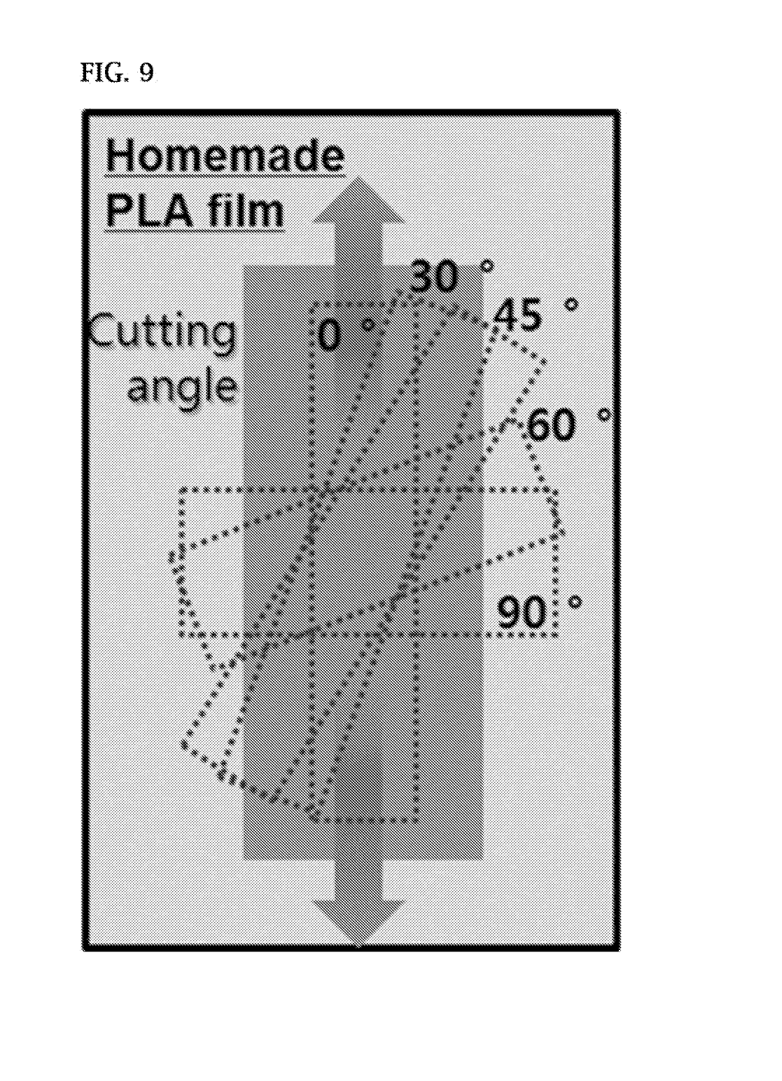

Three types of PSB sensors were used: typical PVDF film-, drawn PLA film-, and PLA nanofiber web-based PSB sensors. For the drawn PLA film, the draw ratio (DR) and the cutting angle were changed (Table 2). Based on the results of dynamic pressure testing, the drawn PLA film having a DR of 5 generated the maximum piezoelectric signal in response to periodic external pressure under the same conditions, and thus the PLA film at a DR of 5 was used for cutting at various angles, as shown in FIG. 9. The PLA nanofiber web-based PSB sensor was manufactured to have the dimensions seen in FIG. 10. Silicone rubber coating was prepared as follows: a silicone elastomer base (Sylgard® 184A) and a carbon black paste were mixed (10:1 w/w), and a silicone elastomer curing agent (10 wt % of the silicone elastomer base) was added. The resulting mixture was allowed to stand in a vacuum desiccator for 20 min, thereby removing air bubbles from the mixture. The resulting solution was spread as thinly as possible on a glass plate, placed in a hot air oven, and maintained at 60° C. for 30 min to precure it. The sensor was superimposed on the precured rubber, placed again in an oven, and maintained at 60° C. for another 30 min to complete curing process. The total thickness of the sensor including the silicone rubber layer was set to about 1.5 mm.

TABLE 2

| | | | | | | |
|---|---|---|---|---|---|---|
| Condition 1: DR | 2 | 3 | 4 | 4.5 | 5 | 5.5 |
| Condition 2: Cutting angle | 0° | 30° | 45° | 60° | 90° | — |

### 1-3-2. Piezoelectric Sensor

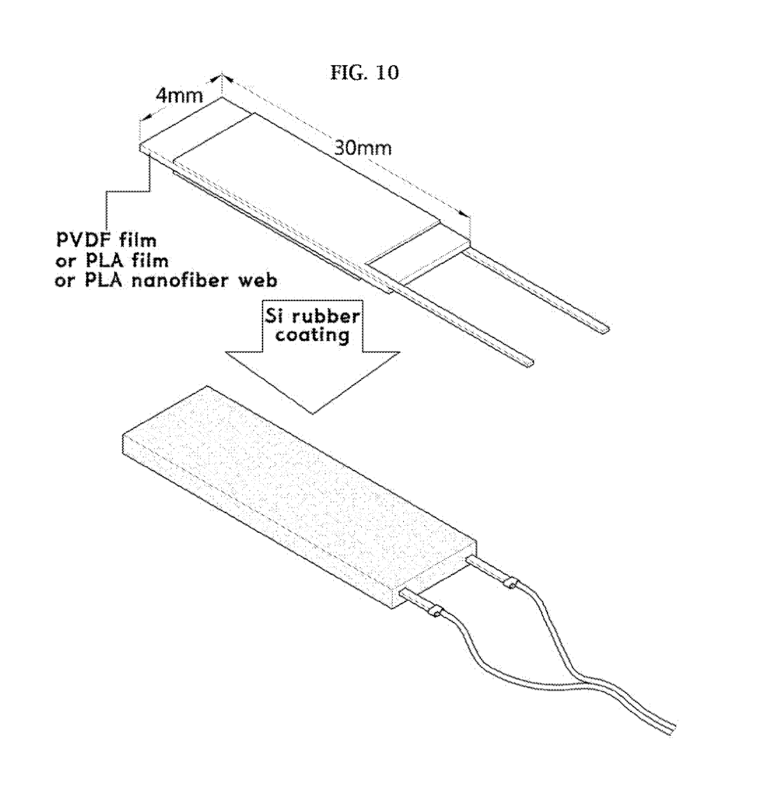

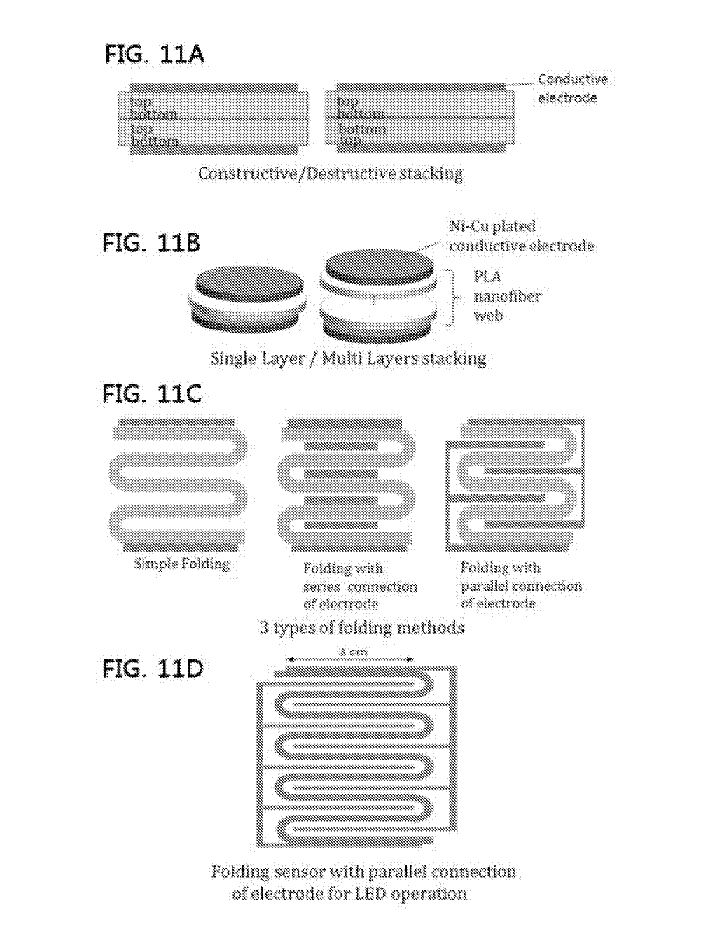

The piezoelectric sensors were manufactured using the drawn PLA films having different DRs and the PLA nanofiber webs. The top and bottom electrodes were manufactured as follows: a Ni—Cu-plated polyester conductive fabric having adhesiveness on one surface thereof and a circular shape was attached to both surfaces of the PLA sample, and the piezoelectric sensor was covered with a piece of clear adhesive tape. To evaluate the specific DR of the PLA film that exhibits the maximum Vₚ₋ₚ (peak to peak voltage), the initial piezoelectric properties of the PLA film were measured. Thereafter, the drawn PLA film was used to manufacture the PSB sensor. For the PLA nanofiber web, the sensors having different structures were manufactured, as shown in FIGS. 11A to 11D. All the sensors, except for the LED operation sensor having larger top and bottom electrode areas, as shown in FIG. 11D, were manufactured to have electrodes having an area of 3.14 cm² at the top and the bottom.

### Test Example 1

### Analysis of Properties of Piezoelectric Material and Piezoelectric Sensor

### 1-1. Test Method

### 1-1-1. Field Emission-Scanning Electron Microscopy (FE-SEM)

To observe the shape of a pure PLA nanofiber web, a FE-SEM device (LEO SUPRA 55, Carl Zeiss Inc., USA) was used.

### 1-1-2. Attenuated Total Reflectance Infrared (ATR-IR) Spectroscopy

ATR-IR is useful in affording information about the chain orientation, physical position and structure of a thick film sample, and measurement thereof is impossible when using the other typical transmission IR mode or grazing incidence reflection absorption mode. In the present invention, using an FTIR spectrophotometer (IFS 66V, Bruker) having diamond crystal accessories (GladiATR™, PIKE), ATR-IR was measured at a resolution of 4 cm⁻¹ with 100 scans. The sample position (MD (machine direction), TD (transverse direction)) and the polarization direction (TE (transverse electric) mode and TM (transverse magnetic) mode) were changed before measurement, and data were recorded using OPUS software.

### 1-1-3. Measurement of PSB Signal

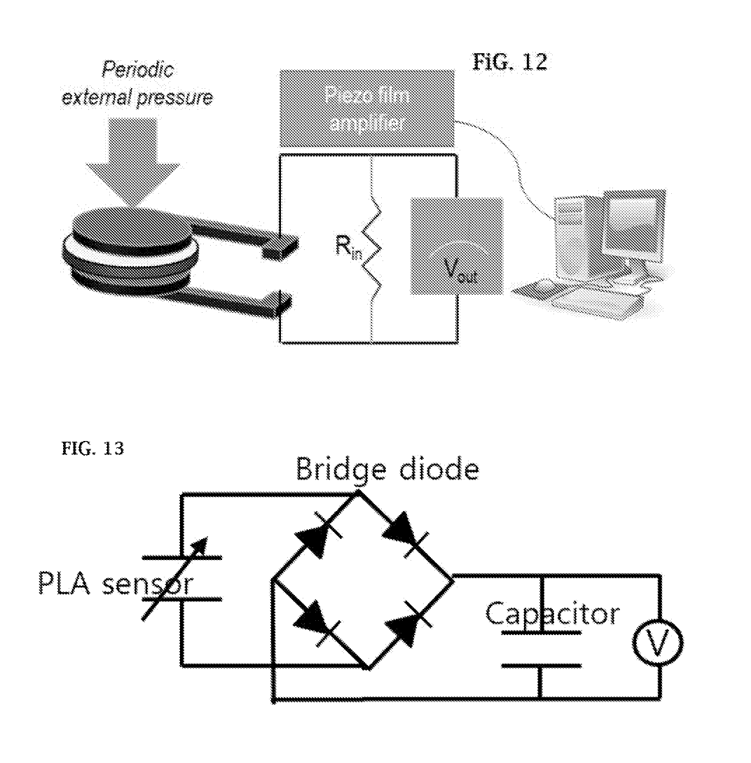

Vₚ₋ₚ was measured using a bespoke dynamic pressure device. The piezoelectric signal generated from the sensor in response to periodic external pressure was transferred to the Piezo Film Lab Amplifier, in which the voltage mode was set to Rᵢₙ of 1 GΩ. Thereafter, the signal was stored in PC through the NIDAQ board, as shown in FIG. 12. To detect the piezoelectric signal, a sinusoidal pressure of 1 kgf at 0.5 Hz was applied to the sensor. For the LED operation testing, a sinusoidal pressure of 6 kgf at 2 Hz was applied to the sensor.

### 1-1-4. Circuit Design and Measurement

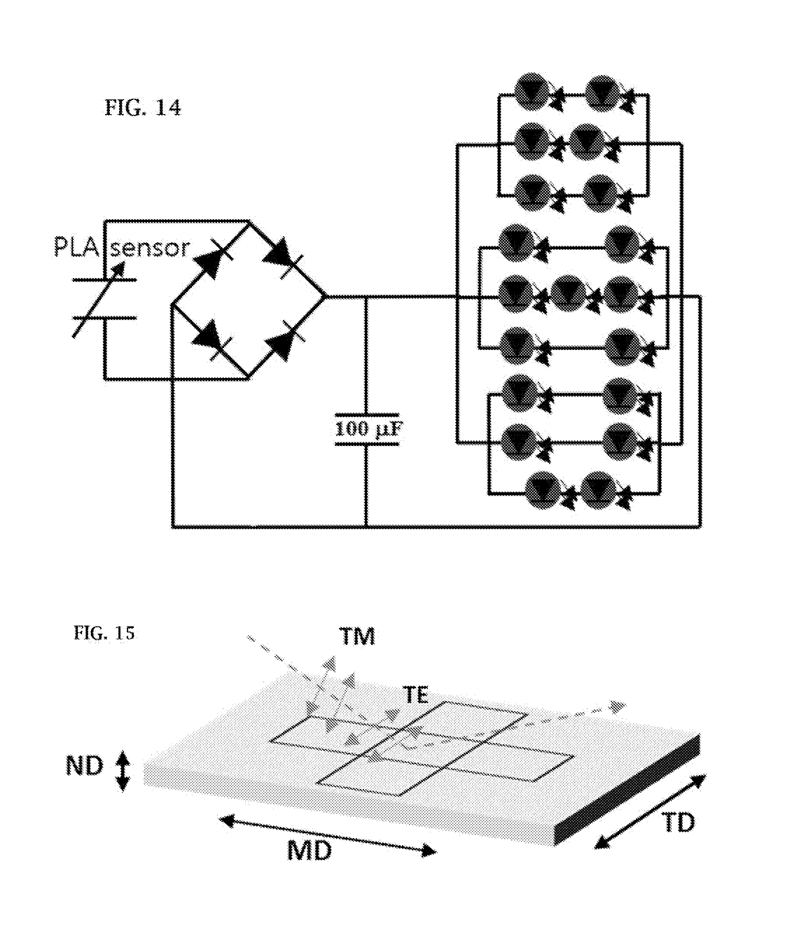

To evaluate the optimal sensor arrangement for charging a capacitor, a nine-layer PLA nanofiber web sensor having electrodes connected in parallel was used. The electrode area was enlarged to 7 cm², and a periodic external pressure of 2 Hz was applied to the PLA sensor. FIG. 13 illustrates the circuit for charging a capacitor using the PLA nanofiber web sensor as a power source. Additionally, the efficiency of operation of the LED was measured using the PLA nanofiber web sensor as a power source. FIG. 14 illustrates the circuit diagram used to operate the LED.

### 1-2. Test Results

### 1-2-1. PSB Sensor Signal

### 1-2-1-1. ATR-IR Analysis

FIG. 15 schematically illustrates the position of the sample on the surface of a diamond used for IR incidence wave ATR-IR spectroscopy for polarization in a TM mode and TE mode. The TM wave polarizes the direction of the electric field such that it is parallel to the incidence surface, and the TE wave polarizes the direction of the electric field such that it is parallel to the surface of the sample. Thus, four different ATR spectra are highly sensitive to dichroism caused by the optical contact and the molecular direction between the surface of the sample and the diamond crystal used for ATR measurement. Furthermore, the ATR spectrum is very sensitive to the effective penetration depth, which varies depending on the polarization direction and the incidence angle of the IR wave. The effective penetration depth (dₑ) of each of the TE and TM waves is calculated by Equation 1 below, where n is the ratio of refractive index of a material to the refractive index of crystal used for ATR measurement (nₘₐₜₑᵣᵢₐₗ/n_{crystal}), λ₁ is the wavelength of IR beam source in the diamond crystal, and θ is the incidence angle. When the incidence angle is set to 45°, the loss of reflective energy is minimized. For this reason, the incidence angle of 45° is the most typical, and thus, the effective penetration depth ratio (dₑ(TM)/dₑ(TE)) of an isotropic sample, such as PDMS-based silicone rubber, is theoretically 2 under the condition that the surface of the sample and the surface of the crystal for ATR are in perfect contact with each other. That is, the absorbance (A_{TM}) of the TM mode spectrum of the polymer sample having randomly arranged chains is two times as strong as the absorbance (A_{TE}) of the TE mode spectrum. Briefly, when A_{TM} approximately doubles A_{TE}, the direction of the polymer chain can be confirmed to be isotropic.

$$\begin{matrix}\frac{{d}_{e} ( TE )}{{λ}_{1}} = \frac{n cos θ}{π ( 1 - {n}^{2} ) {( {sin}^{2} θ - {n}^{2} )}^{1 / 2}} & Equation 1 \\ \frac{{d}_{e} ( TM )}{{λ}_{1}} = \frac{n cos θ ( 2 {sin}^{2} θ - {n}^{2} )}{π ( 1 - {n}^{2} ) [ ( 1 + {n}^{2} ) {sin}^{2} θ - {n}^{2} ] {( {sin}^{2} θ - {n}^{2} )}^{1 / 2}} & \end{matrix}$$

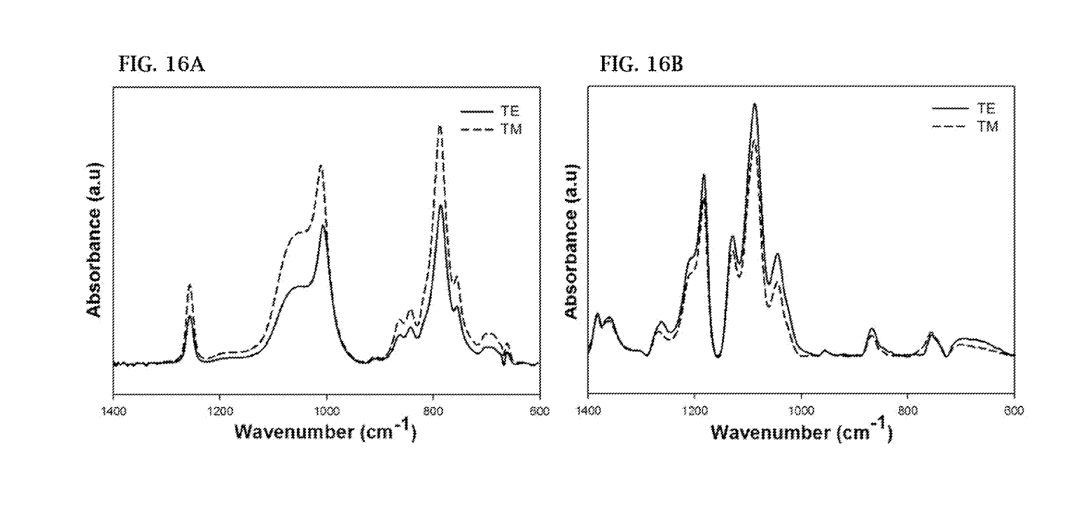

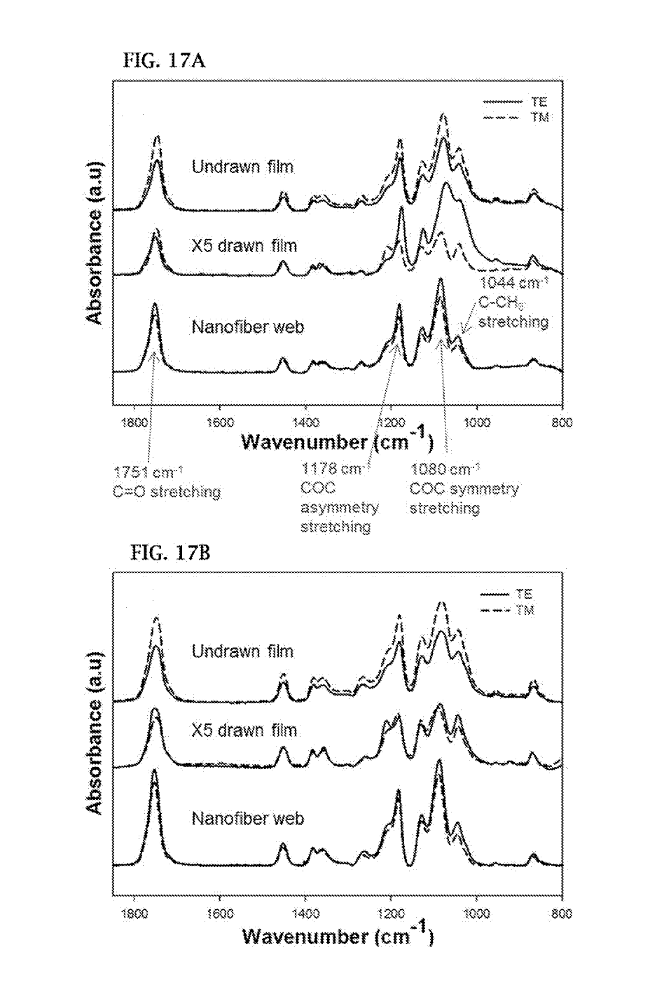

In the present invention, the ATR-IR spectrum peaks of the silicone rubber and the electrospun PLA nanofiber web may be used to understand the direction of the polymer chain. As seen in FIG. 16A, the isotropic silicone rubber exhibited TM mode spectrum absorbance much greater than the TE mode spectrum absorbance in the overall wavelength range (i.e. A_{TE}<<A<2A_{TE}). Meanwhile, the TM mode spectrum (FIG. 16B) of the electrospun PLA nanoweb showed that A_{TM} was not greater than A_{TE}, but that A_{TM} was smaller than A_{TE}, from which it was inferred that a high electric field was applied during electrospinning and thereby preferential chain orientation and/or C═O and C—O—C dipole orientation occurred in the direction of the nanofibers. Furthermore, to compare the degrees of orientation using different methods (undrawn PLA film, drawn PLA film having a DR of 5, and PLA nanofiber web), the ATR-IR spectra of the PLA film samples were measured at positions of MD and TD with respect to the direction of projected light (FIGS. 17A and 17B). The drawn PLA film and the nanofiber web manifested predetermined chain orientation properties, whereas the undrawn PLA film exhibited a spectrum absorbance (FIGS. 17A and 17B) in which A_{TM} was much greater than A_{TE}, as in the silicone rubber (FIG. 16A). For the drawn PLA film, when the sample was positioned in TD, there were no specific changes in peaks in TE and TM modes (FIG. 17B). However, when the position of the sample was changed to MD, there were observed significant changes in C—O—C symmetric (1044 cm¹) and asymmetric stretching (1178 cm¹) bands in TE mode. This is considered to be because the main chain of PLA is arranged parallel to the surface of the sample due to the drawing effect. For the nanofiber web, not only C—O—C symmetric and asymmetric stretching bands but also a C═O stretching band at 1751 cm⁻¹ exhibited strong absorbance compared to the drawn film, regardless of the position (MD or TD) of the sample. Interestingly, the absorbance of the C—O—C symmetric and asymmetric stretching bands was lower in TM mode than in TE mode, but the absorbance difference between TM and TE modes was less than the value observed in the drawn PLA film (DR=5). This means that the electrospun PLA nanofibers had small degrees of chain and dipole orientation compared to the uniaxially drawn PLA film, but had preferential chain and dipole orientation.

### 1-2-1-2. Dynamic Pressure Signal

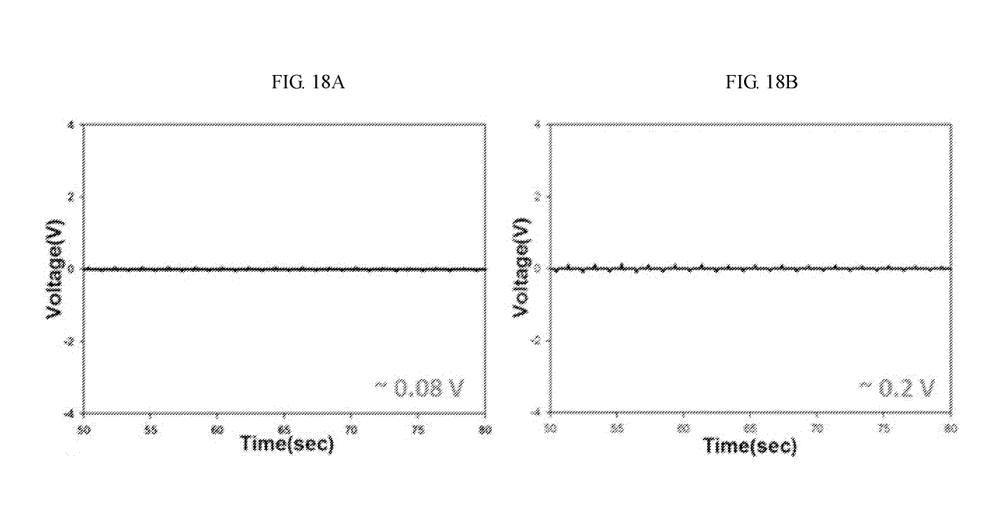

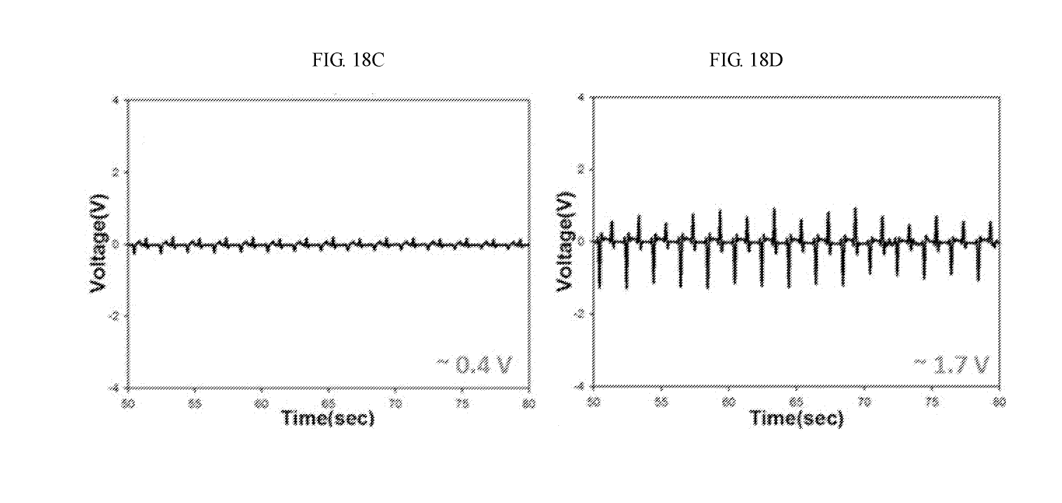

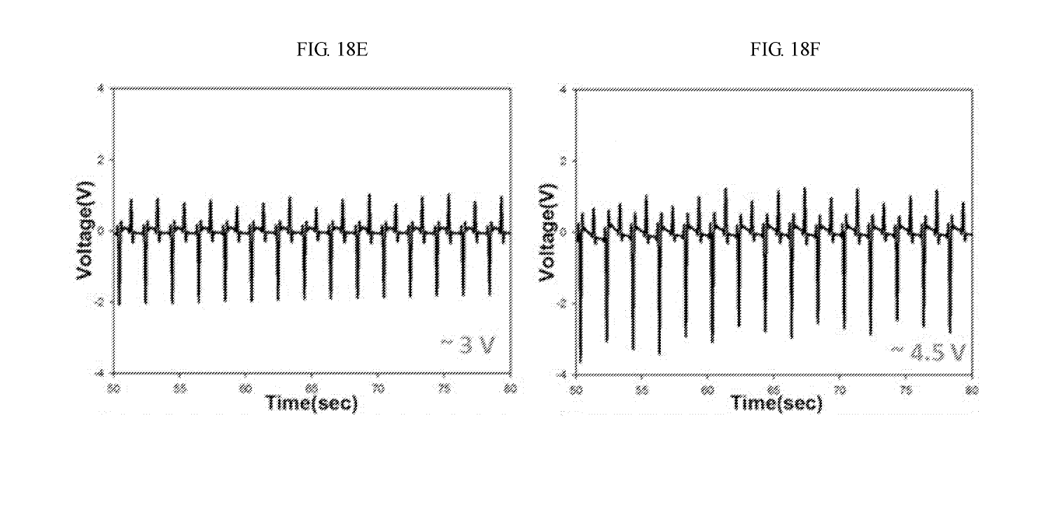

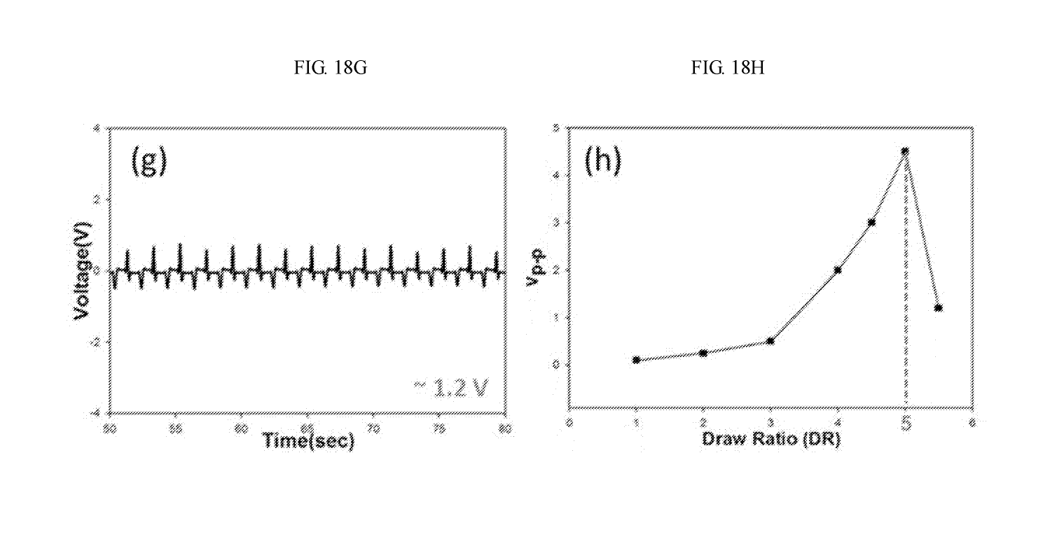

The piezoelectric signals of the sensors manufactured using the PLA films at various draw ratios ranging from 1 to 5.5 were measured using a typical dynamic pressure analyzer. FIGS. 18A to 18G illustrate the results of measurement of piezoelectric voltage signals generated in response to periodic external pressure in the thickness direction at various draw ratios. FIG. 18H illustrates the Vₚ₋ₚ of the PLA films at various draw ratios of FIGS. 18A to 18G. The piezoelectric effect was shown by shear stress in the PLA helical structure in FIG. 3, whereas the piezoelectric signals of the drawn PLA films of FIGS. 18A to 18H were generated due to the deformation of the helical structure when external pressure was applied in the thickness direction, without the need to apply shear stress in the direction in which the sample was drawn. As the draw ratio was increased (DR=5 or more), the PLA helical chains, which are arranged in a uniaxial drawing direction, were stretched, and thus the generation of the piezoelectric signal was non-linearly increased. The stretched helical structure was configured such that preferential chain and dipole orientations were repeated due to shear stress. Hence, the piezoelectric signal, which was generated in response to the dynamic pressure applied in an external direction, was amplified. However, when the tensile stress applied in the drawing direction was greater than the fracture stress of PLA (DR=5.5), the extent of PLA molecular chain and dipole orientation was drastically decreased, and thus Vₚ₋ₚ was significantly lowered at DR=5.5, compared to the maximum Vₚ₋ₚ at DR=5 (FIG. 18H).

### 1-2-1-3. PSB Sensor Signal

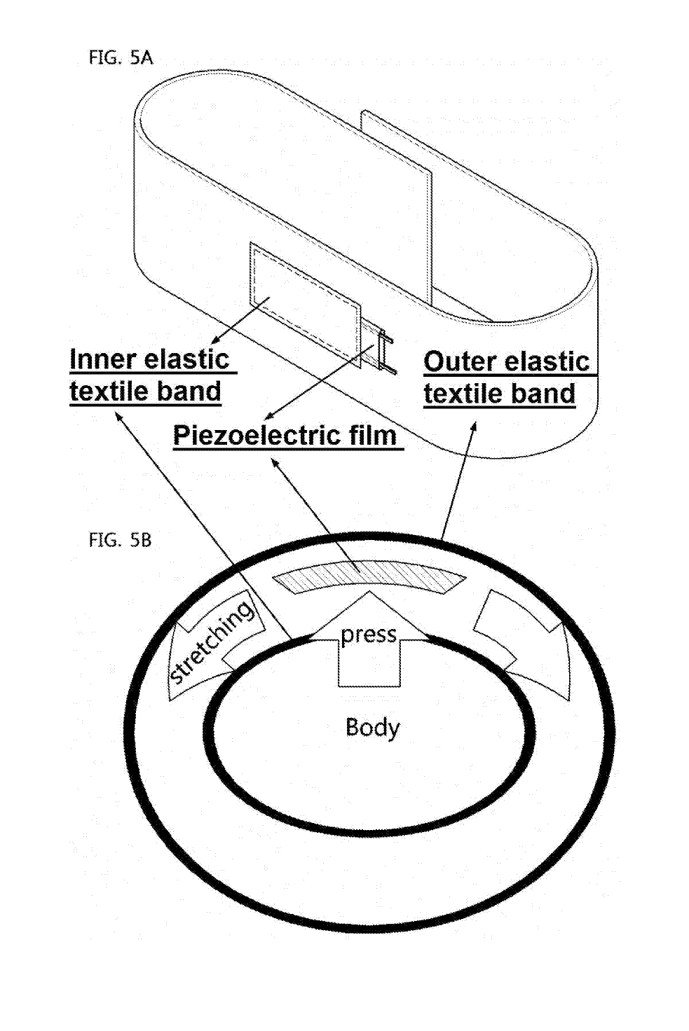

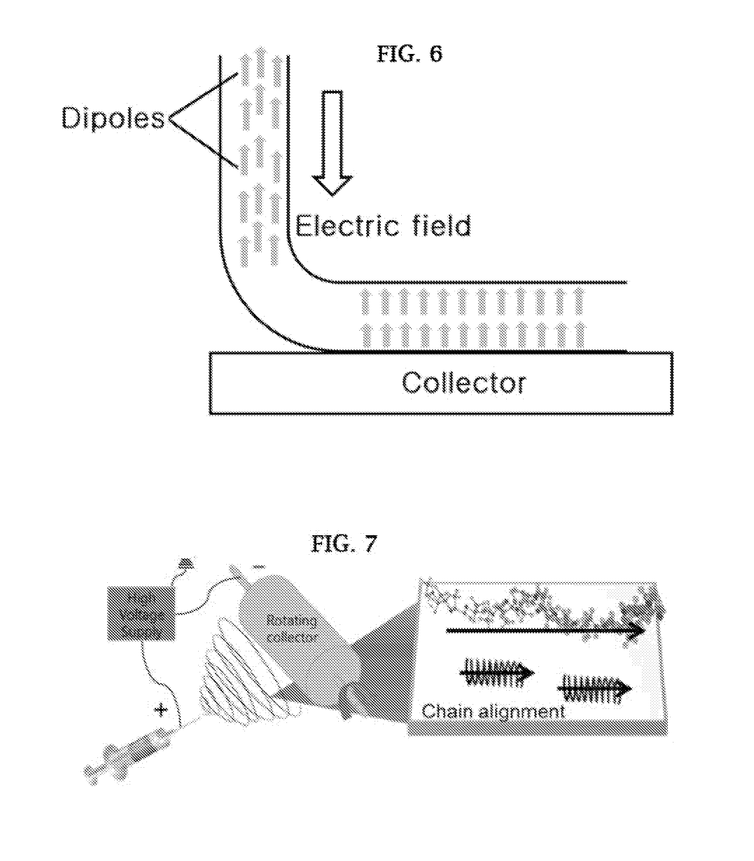

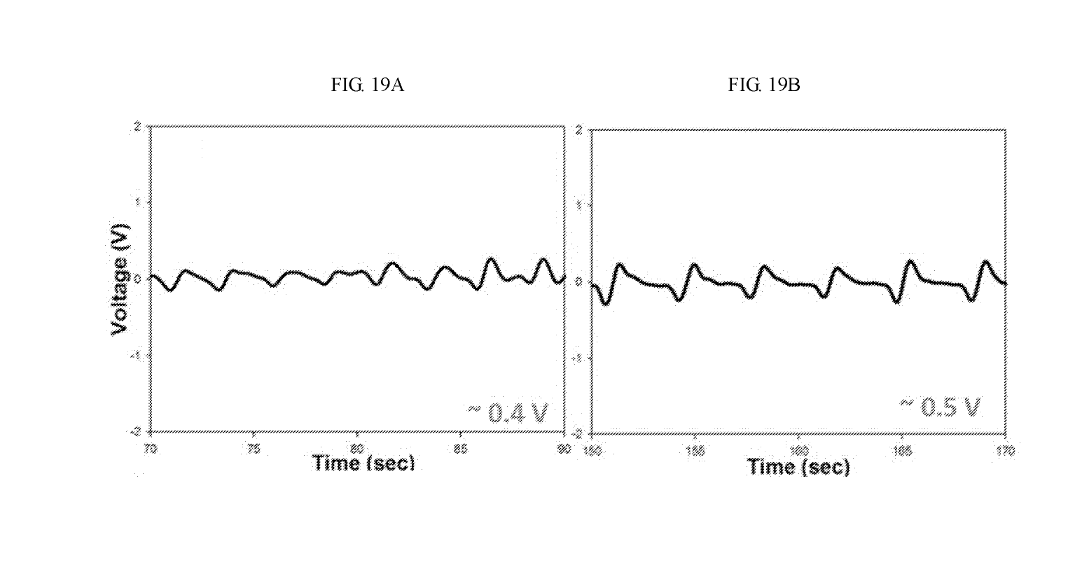

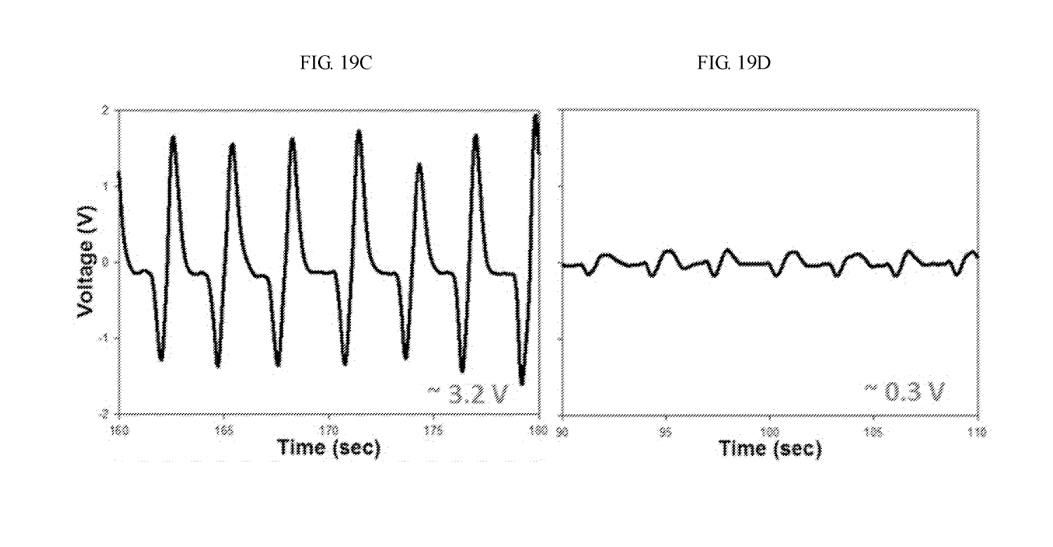

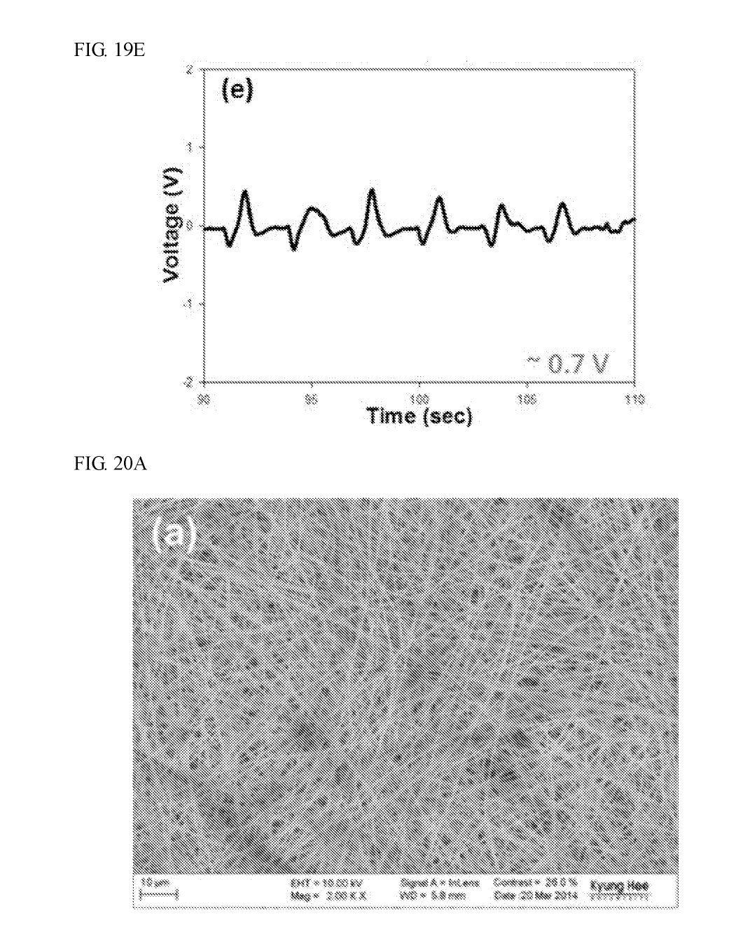

Based on the results of FIGS. 18A to 18H, the PLA film having a DR of 5 was used to manufacture the PSB sensor. The silicone rubber coating sensor (FIGS. 5A and 5B), inserted between elastic textile bands, was manufactured using the drawn PLA film (DR=5), cut at various angles (ranging from 0 to 90°, FIG. 9) relative to the draw direction. The external pressure, which was increased and decreased in the periodic respiratory motion, was applied to PSB, and the PSB sensor made of the PLA film cut at 45° generated a strong signal, about three times as high as those of the samples cut at 0° and 60° (FIGS. 19A to 19E). Unlike the dynamic pressure testing (FIGS. 18A to 18H), measurement of periodic breathing using the PSB sensor was implemented by virtue of the dynamic pressure effect and the stretching effect, but was mainly dependent on the angle at which the film was cut. This is deemed to be because the uniaxially drawn PLA film (DR=5) is already converted into a spherical coil through drawing and the C═O dipoles necessary for generating the piezoelectric signal are arranged in a suitable direction only upon cutting at 45°, thus exhibiting a high pressure signal compared to when cutting at other angles. Due to the increase or decrease in external pressure in the respiratory motion, the PLA chain is regarded as manifesting shear-induced piezoelectric properties. Such a piezoelectric action is different from the drawn PVDF film having linear molecular chains. For the drawn PVDF film, C—F dipoles are preferentially arranged in a direction perpendicular to the stretching direction through uniaxial stretching and then poling.

### 1-2-2. Piezoelectric Sensor Using Electrospun PLA Nanoweb

### 1-2-2-1. FE-SEM

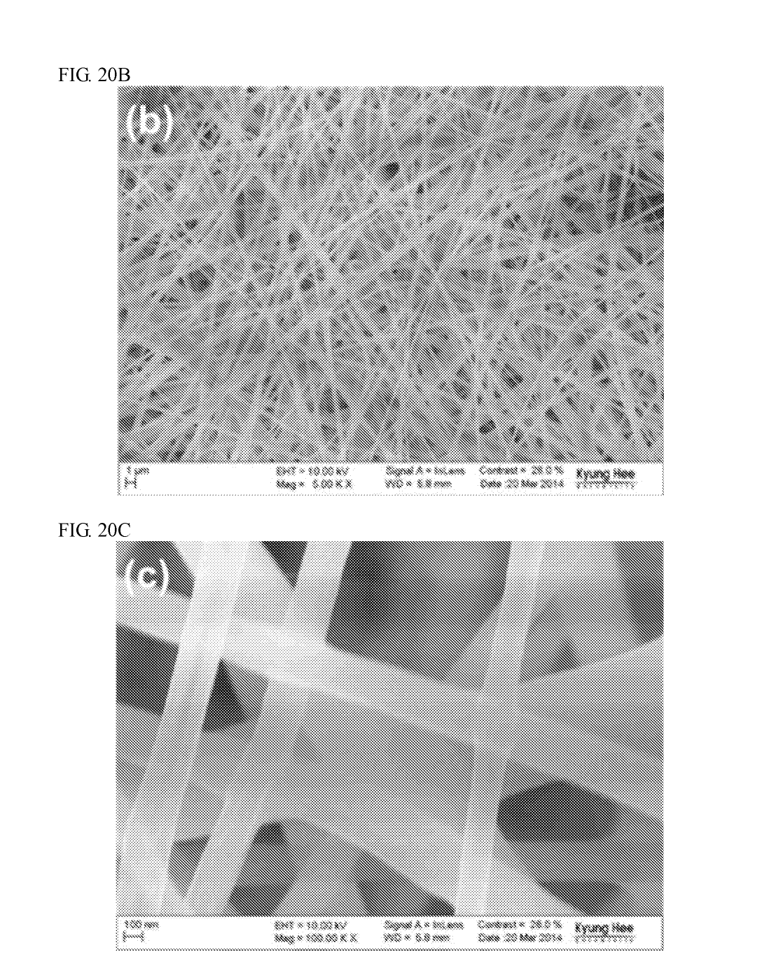

In favor of typical SEM, which has a spatial resolution of 1½ FE-SEM was adopted, due to its superior spatial resolution, which is 3 to 6 times as high, its clarity, and its lower occurrence of image distortion due to static electricity. FIGS. 20A to 20C illustrate the FE-SEM images of the pure PLA nanofiber web obtained by electrospinning the 9 wt % PLA solution, captured at different magnifications (2 k×, k× and 100 k×). Although there is a need for further research into the use of large amounts of fibers having a smaller nano size (diameter 5 to 15 nm), relatively uniform electrospun pure PLA nanofibers having a diameter of 100 nm were produced under the optimal electrospinning conditions established in the present invention. The lump-free uniform morphology is considered to result from optimization of the electrospinning conditions, including voltage, relative viscosity, solvent, solution concentration, and TCD distance of the electrospinning chamber.

### 1-2-2-2. Dynamic Pressure Signal

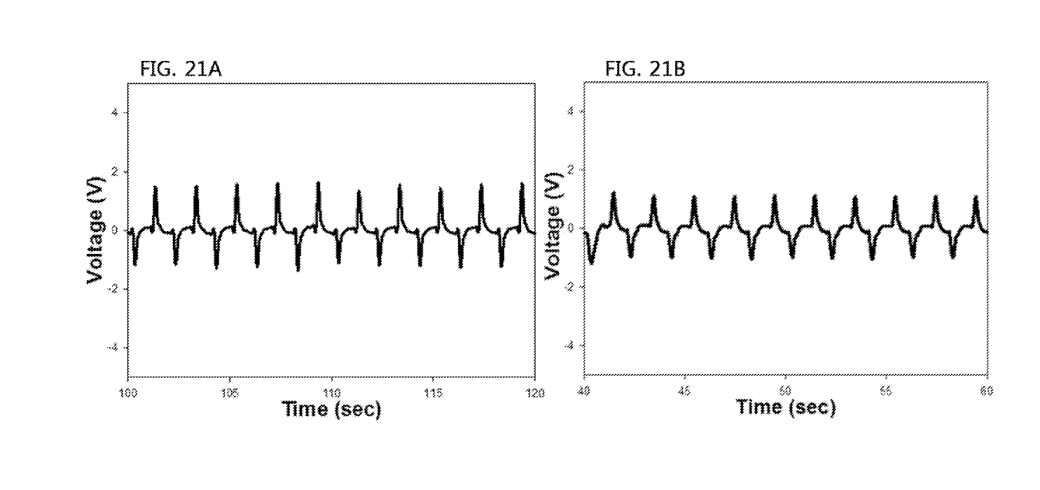

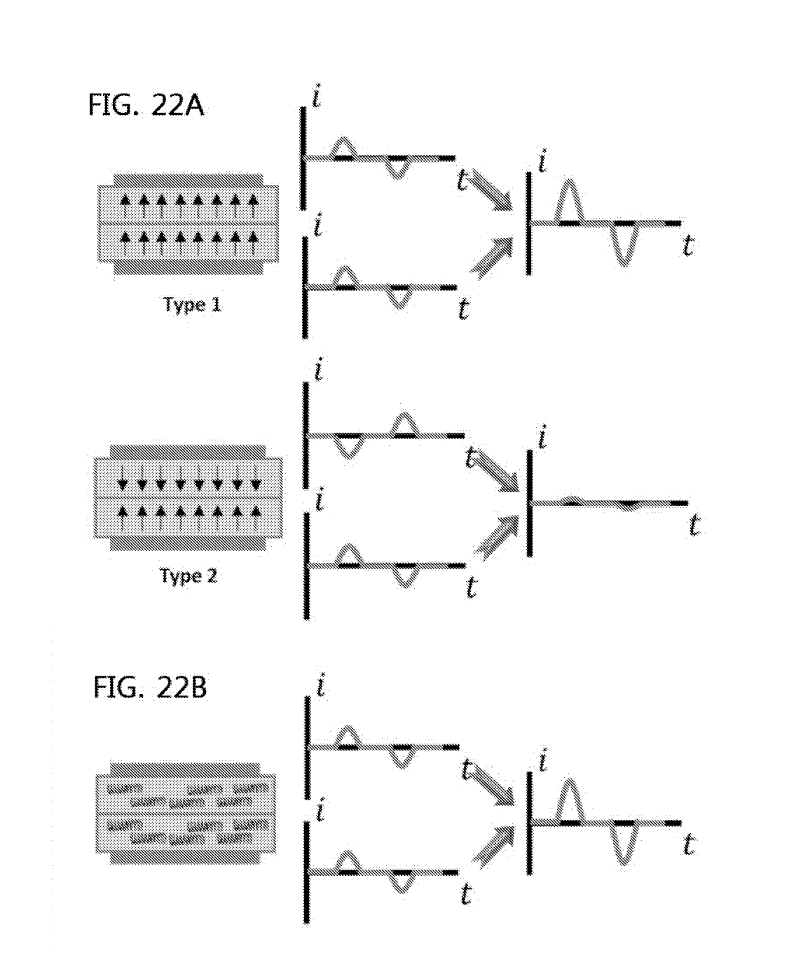

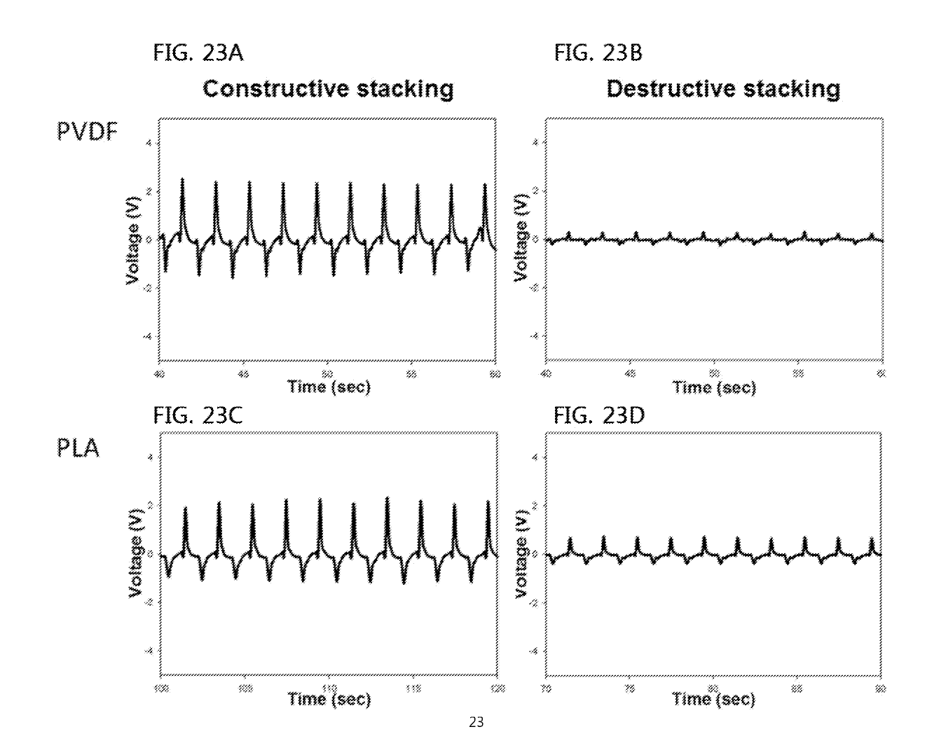

The Vₚ₋ₚ signals of the piezoelectric sensors manufactured from the pure PVDF nanofiber web and the PLA nanofiber web were compared. The results are given in FIGS. 21A and 21B. Under experimental conditions of a predetermined external pressure and Rᵢₙ, the PLA nanofiber web generated a Vₚ₋ₚ of about 3.2 V compared to the PVDF nanofiber web, which generated roughly 3.7 V. FIGS. 22A and 22B schematically illustrate the configurations of the sensors resulting from constructive stacking and destructive stacking using PVDF and PLA nanofiber webs to distinguish the effects attributable to the directional difference of the C—F dipole orientation of linear PVDF and the C═O dipole orientation of helical PLA. For the PVDF nanofiber web, C—F dipoles are usually arranged to any one side, and thus the piezoelectric signal is amplified upon constructive stacking, but disappears upon destructive stacking (FIG. 22A). As described above, the piezoelectric signal of PLA may be preferentially generated by C═O dipoles and may also be created through deformation of a helical structure arranged in a helical direction. Thus, in the PLA sensor, almost the same Vₚ₋ₚ signals are expected to occur in both constructive stacking and destructive stacking (FIG. 22B). However, as shown in FIGS. 23A to 23D, the Vₚ₋ₚ signals of the PVDF and PLA sensors were amplified more upon constructive stacking (FIGS. 23A and 23C) than upon destructive stacking (FIGS. 23B and 23D). The signals of both the constructive stacking PVDF and PLA sensors were amplified compared to the results of FIGS. 22A and 22B. When compared with the destructive stacking PVDF sensor (FIG. 23B), the Vₚ₋ₚ signal of the destructive stacking PLA sensor (FIG. 23D) was amplified. These results showed that, as in the electrospun PVDF nanofiber web, the helical PLA nanofiber web was polarized during electrospinning even without any additional drawing process, meaning that the C═O dipoles were arranged at specific angles.

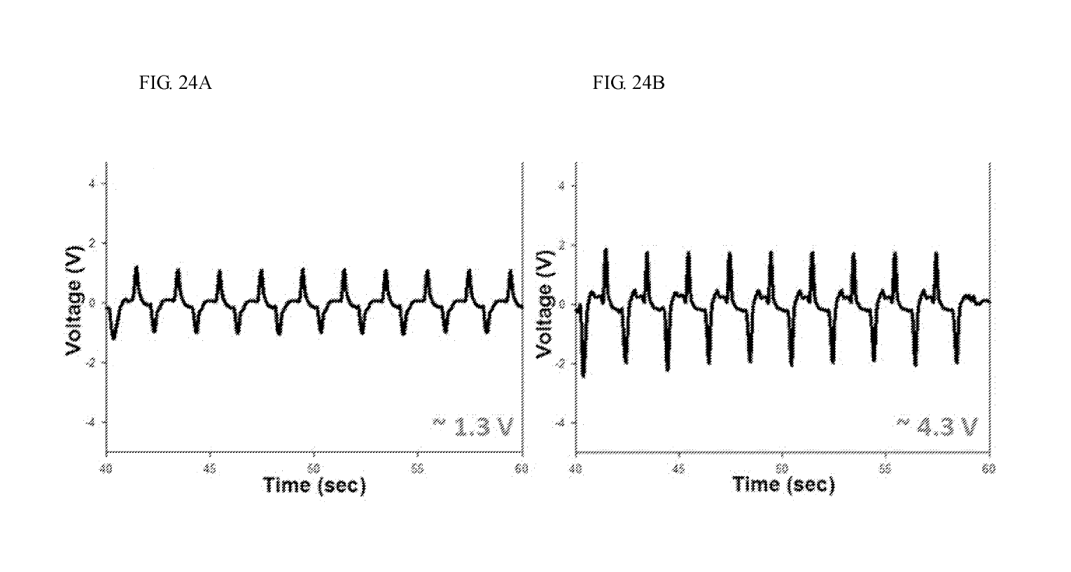

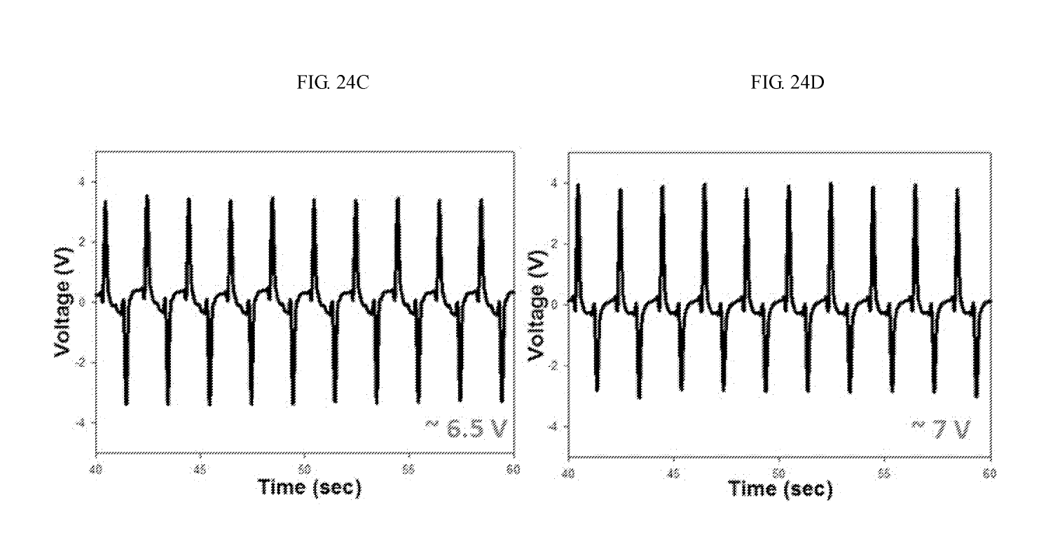

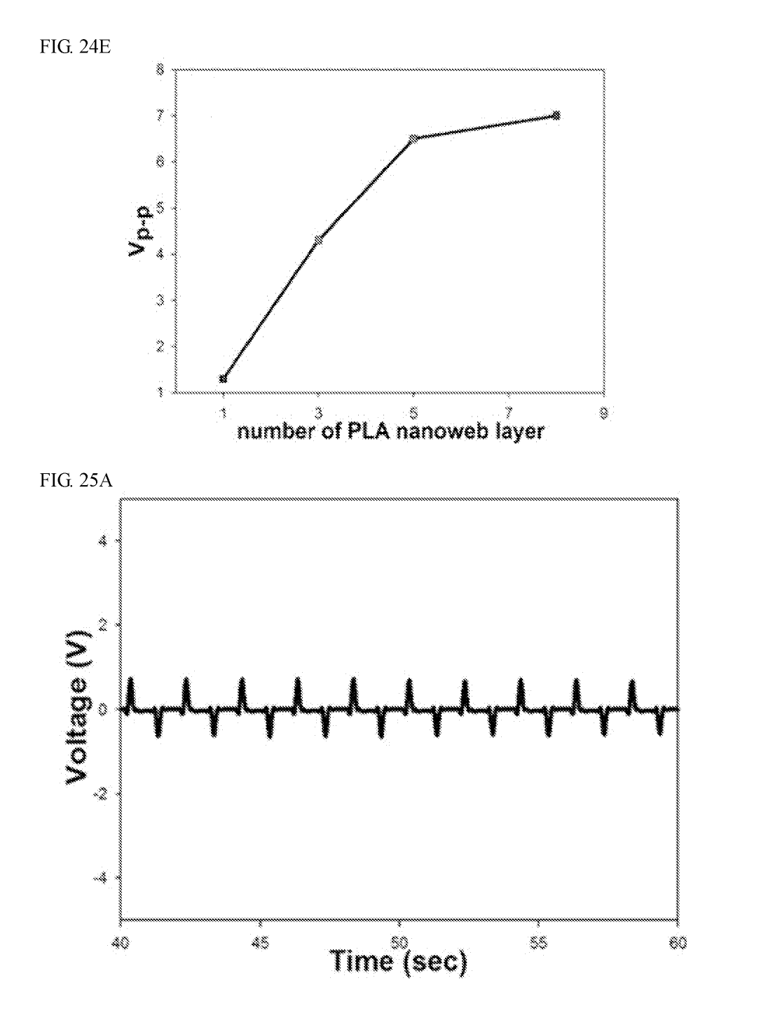

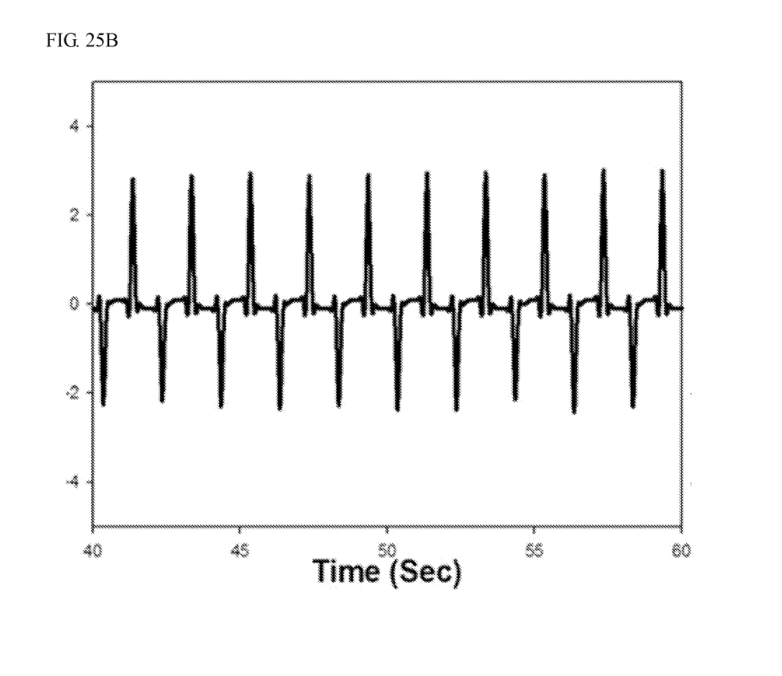

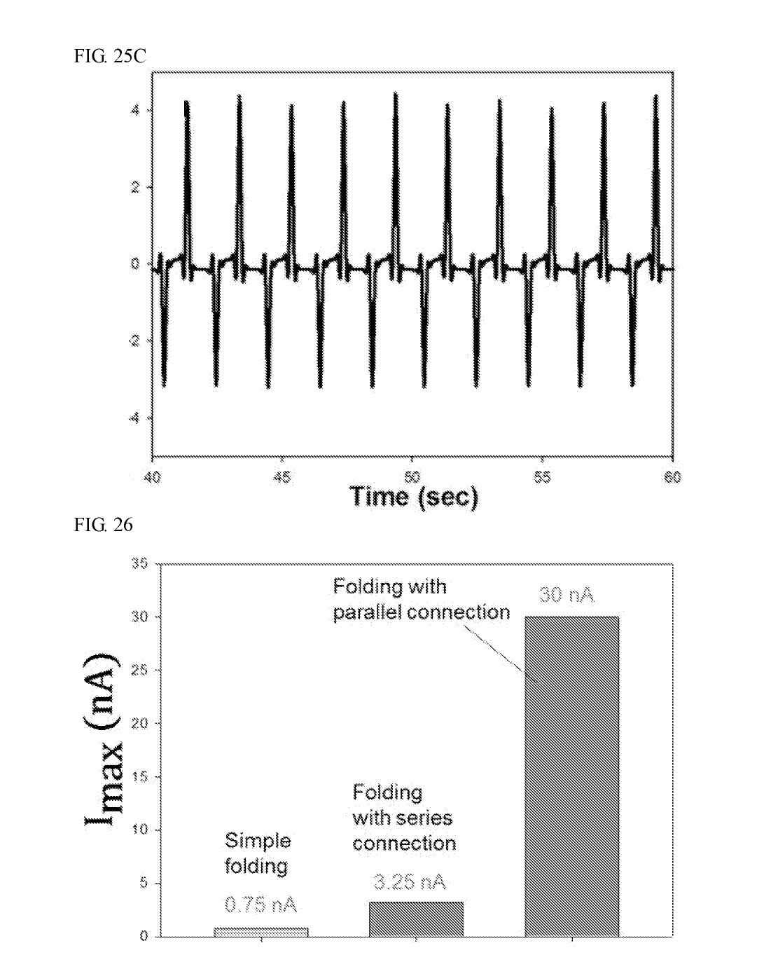

FIGS. 24A to 24E illustrate changes in the piezoelectric signal depending on the number of layers of the PLA nanofiber web. As the number of layers of the PLA nanoweb was increased, the final piezoelectric signal was non-linearly amplified. The generated signals were initially significantly amplified with an increase in the number of layers (up to five layers), but were then appropriately amplified even when the number of layers was further increased, which means that external pressure was limitedly applied to the PLA chains stacked inside. That is, the specific thickness plays an important role in generating the final piezoelectric signal (FIGS. 24A to 24E). To evaluate the effects of three types of folding processes on the piezoelectric signals, additional testing was performed using the PLA nanoweb stacked to five layers. The PLA nanofiber web was folded and the top and bottom electrodes were inserted using different methods to form various configurations (FIGS. 11A to 11D), thus manufacturing three types of piezoelectric sensors. As for simple folding (FIG. 25A) and folding with electrodes connected in series (FIG. 25B), similar to the destructive stacking, the sum of the C═O dipoles of all the layers was remarkably decreased. However, much higher piezoelectric signals were observed in folding with electrodes connected in series rather than simple folding. This is considered to be because the electrodes were inserted between the folded nanowebs, thus increasing the conductivity of all the layers. For folding with electrodes connected in parallel (FIG. 25C), like the parallel connection of batteries, the total area of the electrodes for generating the piezoelectric current was increased, and thus the total value of the generated current was raised, thereby exhibiting significantly amplified piezoelectric signals. The signals generated upon folding with electrodes connected in parallel could not be measured using a NIDAQ board (maximum input voltage±10V) under the condition that output voltage was set to 10 V or more at an input resistance (Rᵢₙ) of 1 GΩ. Hence, measurement was performed in a manner in which the input resistance Rᵢₙ was decreased 10 times to 100 MΩ and thus the output voltage was decreased 10 times. In parallel connection, in which the electrodes are inserted between the folded nanowebs, rather than simple folding, in which the electrodes are positioned only at the top and bottom of the nanoweb stack, the total area of electrodes is enlarged, thereby further increasing the total number of C═O dipoles under the condition that the external pressure is periodically applied. The maximum current (Iₘₐₓ) may be calculated from the maximum peak pressure (Vₘₐₓ) by Equation 2 below. Under the same test conditions, the PLA sensor connected in parallel exhibited piezoelectric current signals about 9 times as high as those of the sensor connected in series, and about 40 times as high as those of the simple folding type sensor (FIG. 26).

$${I}_{max} ( A ) = \frac{{V}_{max} ( V )}{{R}_{i n} ( Ω )} \qquad Equation 2$$

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A nanofiber web piezoelectric material, obtained by electrospinning a spinning solution of polylactic acid in a solvent.

2. The piezoelectric material of claim 1, wherein at least 80% of a monomer for the polylactic acid comprises an L-isomer or a D-isomer.

3. The piezoelectric material of claim 1, wherein the solvent is a mixture comprising chloroform and one of N,N-dimethylacetamide (DMAc), N,N-dimethylformamide (DMF) and dimethylsulfoxide (DMSO).

4. The piezoelectric material of claim 3, wherein the mixture comprises chloroform and one of N,N-dimethylacetamide (DMAc), N,N-dimethylformamide (DMF) and dimethylsulfoxide (DMSO) mixed at a volume ratio of 2:1 to 4:1.

5. The piezoelectric material of claim 4, wherein the spinning solution is prepared by dissolving 5 to 20 wt % of polylactic acid in the solvent.

6. A piezoelectric sensor, comprising the piezoelectric material of claim 1 and electrodes.

7. The piezoelectric sensor of claim 6, wherein the piezoelectric material is folded at least two times and stacked so that same surface portions thereof face each other,
the electrodes are provided between the folded surface portions of the stacked piezoelectric material and on an uppermost surface and a lowermost surface thereof, and
the electrodes, in contact with the same surface portions based on a surface of the unfolded piezoelectric material, are electrically connected to each other.

8. The piezoelectric sensor of claim 6, comprising:
a sensing unit including the piezoelectric material and electrodes formed on both surfaces of the piezoelectric material; and
an elastic layer for wrapping the sensing unit.

9. The piezoelectric sensor of claim 8, wherein the elastic layer comprises silicone rubber.

10. A method of producing a piezoelectric nanofiber web, comprising:
dissolving polylactic acid in a solvent, thus preparing a spinning solution; and
electrospinning the spinning solution, yielding a nanofiber web.

11. The method of claim 10, wherein at least 80% of a monomer for the polylactic acid comprises an L-isomer or a D-isomer.

12. The method of claim 10, wherein the solvent is a mixture comprising chloroform and one of N,N-dimethylacetamide (DMAc), N,N-dimethylformamide (DMF) and dimethylsulfoxide (DMSO).

13. The method of claim 12, wherein the mixture comprises chloroform and one of N,N-dimethylacetamide (DMAc), N,N-dimethylformamide (DMF) and dimethylsulfoxide (DMSO) mixed at a volume ratio of 2:1 to 4:1.

14. The method of claim 13, wherein the spinning solution is prepared by dissolving 5 to 20 wt % of polylactic acid in the solvent.
